(19) United States
(12) Patent Application Publication
(10) Pub. No.: US 2001/0005048 A1
(43) Pub. Date: Jun. 28, 2001

(54) Circuit board arrangement

(76) Inventors: Dieter Krause, Regensburg (DE); Josef Loibl, Regen (DE)

Correspondence Address: MORGAN, LEWIS & BOCKIUS, 1800 M STREET NW, WASHINGTON, DC, 20036-5869, US

(21) Appl. No.: 09/737,483

(22) Filed: Dec. 18, 2000

(30) Foreign Application Priority Data
Dec. 17, 1999 (DE) 199 61 116.5

(51) Int. Cl. H01L 23/495; H01L 23/34; H01L 23/48; H01L 23/52

(52) U.S. Cl. 257/691; 257/668; 257/686; 257/723; 257/700; 257/701; 257/784; 257/786

(57) ABSTRACT

An arrangement for an electrical control circuit. The arrangement comprises a single-layer circuit board includes a first printed circuit; a circuit carrier substrate associated with the single-layer circuit board; a first bonding wire that electrically connects the first printed circuit and the circuit carrier substrate; and a second printed circuit that crosses with respect to the first electrically conductive path at a point. The first bonding wire and the first printed circuit define a first electrically conductive path; and the second printed circuit is electrically insulated from the first electrically conductive path at the point. Because of this arrangement, a potential-free intersection of printed circuits can be made in an especially simple manner.

### CROSS REFERENCE TO RELATED APPLICATIONS

This application claims the benefit of priority based on German Application No. 199 61 116.5, filed Dec, 17, 1999, which is incorporated by reference herein in its entirety.

### BACKGROUND OF THE INVENTION

This application relates to a circuit board arrangement with a single-layer circuit board a circuit carrier substrate associated with the circuit board, and the electrical interconnections between the single-layer circuit board a circuit carrier substrate. In particular, this application can relate to such a circuit board arrangement for a control module in a transmission of a motor vehicle.

In automatic transmissions for motor vehicles, it is believed that the control electronics and associated sensors are increasingly being integrated into the transmission. Similar requirements of “on-site electronics” are also believed to exist in engine and brake controls, for example. It is believed that mechatronic control modules, as they are called, use flexible circuit boards or flexible films to distribute electrical signals and energy. For economic reasons, it is believed that single-layer circuit boards are preferred. Because of the circuit technology or the circuit board layout, however, it is believed that a potential-free crossing or disentanglement of printed circuits may be necessary.

World Patent Document No. WO 98/44593 is believed to disclose a control module that is hermetically sealed against oil. It is further believed that a flexible circuit board extends into and is sealed with respect to a housing of the control module, and is in electrical communication with a ceramic substrate in a mutually overlapping area by way of an adhesive. It is believed that electrical signals from sensors are fed over printed circuits on the flexible circuit board to an integrated control circuit mounted on the ceramic substrate.

German Patent Document No. 41 18 308 A1 is believed to describe a circuit carrier that consists of a first circuit board and a second circuit board glued onto the first circuit board. Electrical connections between the first circuit board and an electronic component on the second circuit board are provided by bonding wires. Printed circuits or resistors mounted in thick coating technology can be located on the first circuit board under the second circuit board.

It is believed that there is a need to provide a circuit arrangement with a single-layer circuit board that permits an especially streamlined production of intersections between electrically conductive paths that are electrically insulated from each other. It is further believed that there is a need to provide such a circuit arrangement that does not require additional manufacturing processes.

### SUMMARY OF THE INVENTION

The present invention provides an arrangement for an electrical control circuit. The arrangement comprises a single-layer circuit board includes a first printed circuit; a circuit carrier substrate associated with the single-layer circuit board; a first bonding wire that electrically connects the first printed circuit and the circuit carrier substrate; and a second printed circuit that crosses with respect to the first electrically conductive path at a point. The first bonding wire and the first printed circuit define a first electrically conductive path; and the second printed circuit is electrically insulated from the first electrically conductive path at the point.

### BRIEF DESCRIPTION OF THE DRAWINGS

The accompanying drawings, which are incorporated herein and constitute part of this specification, illustrate presently preferred embodiments of the invention, and, together with the general description given above and the detailed description given below, serve to explain features of the invention.

FIG. 1 is a partial view of an electrical control circuit arrangement according to a preferred embodiment for a transmission control module.

FIG. 2 is a top view of the circuit board arrangement shown in FIG. 1.

### DETAILED DESCRIPTION OF A PREFERRED EMBODIMENT

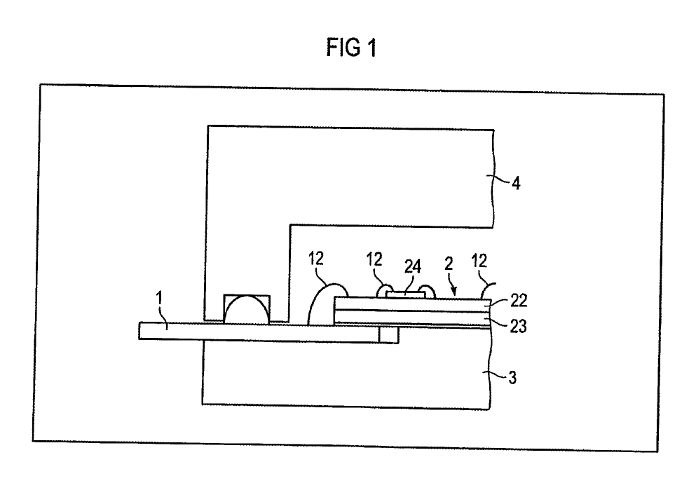

FIG. 1 shows a transmission control module with an electrical control circuit arrangement that comprises a single-layer flexible circuit board 1, e.g., a flexible film such as polyimide, and a circuit carrier substrate 2, e.g., comprising a ceramic material. The circuit carrier substrate 2 includes two layers 22 and 23, which each have at least one printed circuit. Electrical connections can be made between the circuit board 1 and the circuit carrier substrate 2 with bonding wires 12. Accordingly, printed circuits 11 on the circuit board 1 can be electrically connected with printed circuits 21 on circuit carrier substrate 2.

The flexible circuit board 1 and the circuit carrier 2 have respective overlapping areas in which the circuit carrier substrate 2 and the circuit board 1 can be glued together.

According to a preferred embodiment, the control module is intended for installation within a transmission housing (not shown) of a motor vehicle (not shown).

At least one electronic component 24 can be mounted on the circuit carrier substrate 2. According to a preferred embodiment, the electronic component 24 can include a semiconductor chip, without a housing, and an integrated control circuit. The electronic component 24 can be electrically connected to bonding spots or bonding pads, or with the printed circuits 21, on the circuit carrier substrate 2 via the bonding wires 12. According to a preferred embodiment, all of the bonding wires 12 can be mounted in a single manufacturing process using thick-strand wire bonding.

The flexible circuit board 1 can extend through a housing, which can be rotationally symmetric, and which can include a base plate 3, e.g., comprising a metallic material, and a cover 4, e.g., comprising a plastic material. In order to provide a seal against ambient conditions, e.g., transmission fluid, the underside of the circuit board 1 can be laminated with the base plate 3. Additionally, the cover 4 can have a generally peripheral groove that confronts the upper side of the circuit board 1, and in which a gasket or sealing medium can be located.

The circuit carrier substrate 2 can be glued, e.g., using a heat conductive adhesive, on a raised portion or platform of the base plate 3. The height of the platform generally corresponds to the approximate thickness of the circuit board 1.

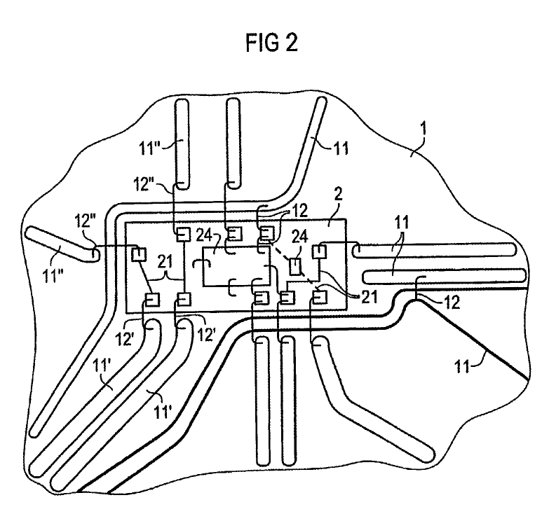

Referring to FIG. 2, the circuit board 1 can include one or more of the printed circuits 11. Additionally, the circuit board 1 can include one or more sensors, one or more actuators, or one or more plug connectors (none of which are shown) that provide, in combination with the printed circuits 11 and the electrical components 24 on the circuit carrier substrate 2, an electrical control circuit. The bonding wires 12 can be connected, e.g., by welding, to the printed circuits 11 of the circuit board 1 and to the bonding spots or bonding pads on the circuit carrier substrate 2.

Additionally, the bonding wires 12, or bond bridges, can provide electrical communication between respective printed circuits 11 on the circuit board 1, or can provide electrical communication between the bonding spots or bonding pads on the circuit carrier substrate 2 and electrical components 24 on the circuit carrier substrate 2.

As shown in FIG. 2, the circuit board 1 can include a plurality of the electrical printed circuits 11. These electrical printed circuits can include, for example, signal wires that can each have a width of about 1 millimeter (and which can, for example, electrically connect a connector pin directly to a solenoid valve) and energy supply lines that can each have a width of about 2 millimeter. Various bonding wires 12 are shown passing over such signal wire printed circuits and such energy supply line printed circuits. The length of a bonding wire 12 or bonding loop depends on the number and width of the printed circuits 11 that pass under the bonding wire 12. For example, a bonding wire 12 may be long enough to pass over at least two of the 2 millimeter wide energy supply lines, or may be long enough to pass over at least five of the 1 millimeter wide signal wires.

Electrical paths are also shown in FIG. 2. Such electrical paths can include a first printed circuit 11′ that is electrically connected by a bonding wire 12′ to the circuit carrier substrate 2. Additionally, these electrical paths can further include a printed circuit 21 of the circuit carrier substrate 2 that extends from the bonding wire 12′ to another bonding wire 12″, which electrically connects the printed circuit 21 to a second printed circuit 11″ of circuit board 1. Therefore, such an electrical path can electrically connect, via two bonding wires 12′, 12″ and the printed circuit 21, two printed circuits 11′ and 11″ of the circuit board 1. Like other bonding wires 12, the bonding wires 12″ can cross, and be electrically insulated from, various printed circuits 11 on the circuit board 1.

On circuit carrier substrate 2, an electrical path can cross, and be electrically insulated with respect to, another electrical path at a different layer 22, 23 of the circuit carrier substrate. For example, a dotted line indicates a printed circuit 21 at the lower layer 23 of the circuit carrier substrate 2. This dotted-line printed circuit 21 crosses another printed circuit 21 (shown in solid line) that can be at the upper layer 22 of the circuit carrier substrate 2.

Printed circuits on a single-layer circuit board can be disentangled using bonding wires and additional circuit carrier substrates that may also be present. Accordingly, it is possible to eliminate soldering of wire bridges since bonding wires can be used in the electrical paths that connect to the circuit carrier substrate. Thus, an additional manufacturing step can be made unnecessary. Bonding along the electrical paths can be performed together with bonding electrical connections between electronic components that are mounted on the circuit carrier substrate.

The electrical paths can cross, and can be electrically insulated with respect to the point of crossing, either by using a bonding wire or by placing printed circuits on different layers of a circuit carrier substrate.

Preferred embodiments can be applicable to transmission control modules, engine control modules, or brake control modules. In general, these modules include an electronic control circuit that is at least partially mounted on a ceramic substrate.

While this application discloses certain preferred embodiments, numerous modifications, alterations, and changes to the described embodiments are possible without departing from the sphere and scope of the disclosure, as defined in the appended claims. Accordingly, it is intended that this application not be limited to the described embodiments, but that it have the full scope defined by the language of the following claims, and equivalents thereof.

What is claimed is:

1. An arrangement for an electrical control circuit, the arrangement comprising:
a single-layer circuit board including a first printed circuit;
a circuit carrier substrate associated with the single-layer circuit board;
a first bonding wire electrically connecting the first printed circuit and the circuit carrier substrate, the first bonding wire and the first printed circuit defining a first electrically conductive path; and
a second printed circuit crossing with respect to the first electrically conductive path at a point, the second printed circuit being electrically insulated from the first electrically conductive path at the point.

2. The arrangement according to claim 1, wherein the circuit carrier substrate comprises a third printed circuit, the single-layer circuit board comprises a fourth printed circuit, and a second bonding wire electrically connects the third and fourth printed circuits, and wherein the electrically conductive path comprises the first printed circuit, the first bonding wire, the third printed circuit, the second bonding wire, and the fourth printed circuit.

3. The arrangement according to claim 1, wherein the second printed circuit crosses under the first bonding wire at the point.

4. The arrangement according to claim 1, wherein the circuit carrier substrate comprises a first layer and a second layer, the first layer at least partially defines the first electrically conductive path, and the second layer at least partially defines a second electrically conductive path, and wherein the first and second electrically conductive paths cross one another at their respective layers.

5. The arrangement according to claim 1, wherein the circuit carrier substrate comprises a ceramic material.

6. The arrangement according to claim 5, wherein the single-layer circuit board comprises a material that is relatively flexible with respect to the circuit carrier substrate.

7. The arrangement according to claim 1, wherein the circuit carrier substrate includes an electronic component, and the first bonding wire electrically connects the first printed circuit and the at least one electronic component.

8. The arrangement according to claim 7, wherein the circuit carrier substrate includes a bonding pad and the first bonding wire electrically connects the first printed circuit to the bonding pad, and wherein a second bonding wire electrically connects the bonding pad to the electronic component.

9. The arrangement according to claim 1, wherein the single-layer circuit board includes a third printed circuit, and wherein a second bonding wire electrically connects the first and third printed circuits.
